(19) United States
(12) Patent Application Publication
(10) Pub. No.: US 2023/0371405 A1
(43) Pub. Date: Nov. 16, 2023

(54) PHASE CHANGE HETEROSTRUCTURES WITH CONTROLLED LINEAR DYNAMIC RANGE

(71) Applicant: INTERNATIONAL BUSINESS MACHINES CORPORATION, ARMONK, NY (US)

(72) Inventors: Kevin W. Brew, Niskayuna, NY (US); JIN PING HAN, Yorktown Heights, NY (US); Timothy Mathew Philip, Albany, NY (US); Cheng-Wei Cheng, White Plains, NY (US); ROBERT L. BRUCE, White Plains, NY (US); Matthew Joseph BrightSky, Armonk, NY (US)

(21) Appl. No.: 17/663,236

(22) Filed: May 13, 2022

(51) Int. Cl. H01L 45/00

(52) U.S. Cl. CPC H01L 45/06; H01L 45/14

(57) ABSTRACT

A structure comprising a top electrode and a bottom electrode. The structure further comprises a multilayer stack disposed between the top electrode and the bottom electrode, where the multilayer stack comprises alternating confinement layers and phase-change material layers, and where at least two of the phase-change material layers have different doping concentrations of at least one dopant.

### BACKGROUND

The present disclosure relates to analog hardware, and, more specifically, to analog hardware utilizing phase-change materials (PCMs).

PCMs can exist in at least two different states such as amorphous and crystalline. The amorphous state can have a disordered atomic structure while the crystalline state can be polycrystalline in nature. The amorphous state and the crystalline state have different electrical properties. For example, in an amorphous state, some PCMs have a resistivity high enough to be considered an insulator (e.g., they behave as an open circuit). On the other hand, in the crystalline state, the same PCM can have a lower resistivity and may behave as a resistor.

Heating a PCM to a particular temperature for a particular time switches phases from one (e.g., amorphous phase) state to a second (e.g., crystalline phase) state. Reheating to another particular temperature and another particular time reverses phases from the second phase back to the first phase. Accordingly, PCMs can be selectively set and reset between states, and such state switching can be correlated to ones and zeroes for programming purposes.

### SUMMARY

Aspects of the present disclosure are directed toward a structure comprising a top electrode and a bottom electrode. The structure further comprises a multilayer stack disposed between the top electrode and the bottom electrode. The multilayer stack comprises alternating confinement layers and phase-change material layers. At least two of the phase-change material layers have different doping concentrations of at least one dopant.

Additional aspects of the present disclosure are directed toward a structure comprising a top electrode and a bottom electrode. The structure further comprises a multilayer stack disposed between the top electrode and the bottom electrode. The multilayer stack comprises alternating confinement layers and phase-change material layers. At least two of the phase-change material layers have different thicknesses.

Additional aspects of the present disclosure are directed toward a structure comprising a top electrode and a bottom electrode. The structure further comprises a multilayer stack disposed between the top electrode and the bottom electrode. The multilayer stack comprises alternating confinement layers and phase-change material layers. At least two of the phase-change material layers have different doping concentrations, and at least two of the phase-change material layers have different thicknesses.

The present summary is not intended to illustrate each aspect of, every implementation of, and/or every embodiment of the present disclosure.

### BRIEF DESCRIPTION OF THE DRAWINGS

The drawings included in the present application are incorporated into and form part of the specification. They illustrate embodiments of the present disclosure and, along with the description, serve to explain the principles of the disclosure. The drawings are only illustrative of certain embodiments and do not limit the disclosure.

FIG. 1 illustrates a block diagram of an example phase-change heterostructure (PCH) with graded dopant in alternating phase-change material (PCM) layers, in accordance with some embodiments of the present disclosure.

FIG. 2 illustrates a block diagram of an example PCH with graded thickness in alternating PCM layers, in accordance with some embodiments of the present disclosure.

FIG. 3 illustrates a flowchart of an example method for fabricating a PCH structure, in accordance with some embodiments of the present disclosure.

FIG. 4A illustrates a block diagram of a PCH structure after patterning, in accordance with some embodiments of the present disclosure.

FIG. 4B illustrates a block diagram of a PCH structure after encapsulation and interlayer dielectric (ILD) backfill, in accordance with some embodiments of the present disclosure.

FIG. 4C illustrates a block diagram of a PCH structure after attaching a contact from an upper metal layer, in accordance with some embodiments of the present disclosure.

While the present disclosure is amenable to various modifications and alternative forms, specifics thereof have been shown by way of example in the drawings and will be described in detail. It should be understood, however, that the intention is not to limit the present disclosure to the particular embodiments described. On the contrary, the intention is to cover all modifications, equivalents, and alternatives falling within the spirit and scope of the present disclosure.

### DETAILED DESCRIPTION

Aspects of the present disclosure are directed toward analog hardware, and, more specifically, to analog hardware utilizing phase-change materials (PCMs). While not limited to such applications, embodiments of the present disclosure may be better understood in light of the aforementioned context.

Memristive devices can refer to electrical resistance switches capable of retaining one or more states of internal resistances based on a history of voltage and/or current. Such memristive devices can store and process information and can realize improved performance characteristics relative to conventional integrated circuit technology.

Phase change heterostructures (PCH) are multilayer stacks with layers alternating between PCM layers and confinement layers. Such PCHs can improve read resistance noise and reduce drift in analog memristive devices. However, cell resistance is lower for PCHs and the conductance curve has limited linear dynamic range.

Aspects of the present disclosure are directed to PCHs having alternating confinement layers and PCM layers. In some embodiments, the PCM layers have variable resistance values through the PCH. The variable resistance in the PCM layers can be realized by different doping concentrations in the PCM layers, different dopants in the PCM layers, and/or different thicknesses of the PCM layers and/or the confinement layers. In some embodiments, the PCM layers can have a similar crystallinity temperature (T_{c}).

Advantageously, aspects of the present can tune the conductance change (ΔG) throughout the PCH and/or increase the dynamic range (e.g., approaching linearity) for the PCH as a result of the variable resistance through the PCH and/or the similar T_{c} of the PCM layers. Tuning the conductance change (ΔG) throughout the PCH and/or increasing the dynamic range can give the PCH more states to program, more control (e.g., accuracy) of the programming, and/or a larger on/off (R_{SET}/R_{RESET}). Other advantages include, but are not limited to, reduced resistance read noise, reduced programming current due to multilayer heat trapping, tighter drift coefficient distribution (e.g., via the non-drifting confinement layers), increased stability (e.g., endurance, longevity, etc.) of doped PCM layers through frequent cycling (e.g., as a result of the confinement layers and similar T_{c}), and/or ease of manufacture (e.g., using co-sputtering chambers).

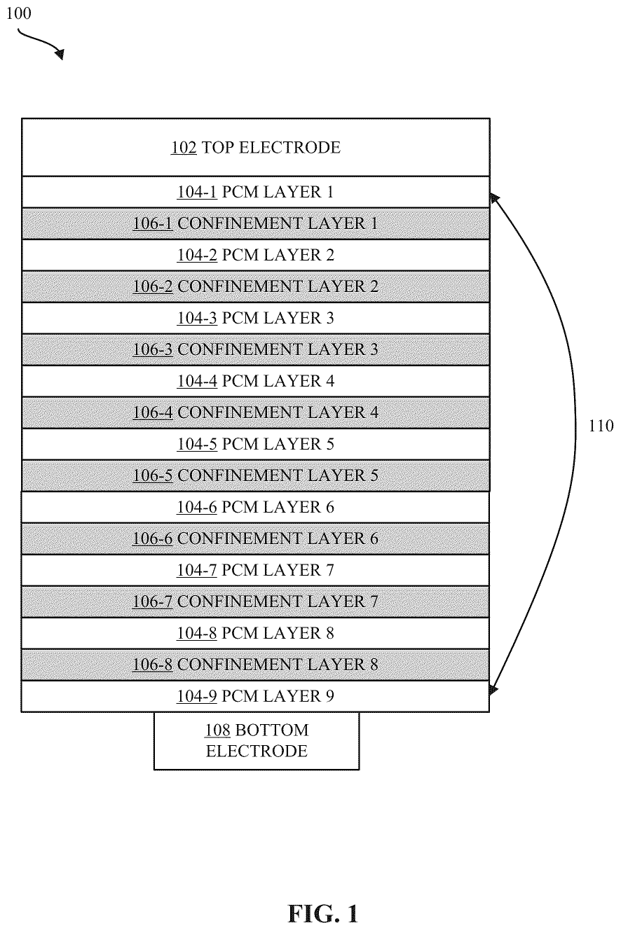

Referring now to the figures, FIG. 1 illustrates a block diagram of an example PCH 100 with graded dopant in alternating PCM layers 104, in accordance with some embodiments of the present disclosure. The PCH 100 includes a multilayer stack 110 disposed between a top electrode 102 and a bottom electrode 108. In some embodiments, the bottom electrode 108 is of smaller size than the top electrode 102. The multilayer stack 110 comprises alternating PCM layers 104 and confinement layers (CLs) 106.

The PCM layers 104 include a plurality of PCM layers of similar or dissimilar PCM material (now known or later developed), with similar or dissimilar dopant concentrations of similar or dissimilar dopants (now known or later developed). The PCM layers 104 include eight layers (e.g., PCM layer 1 104-1, PCM layer 2 104-2, PCM layer 3 104-3, PCM layer 4 104-4, PCM layer 5 104-5, PCM layer 6 104-6, PCM layer 7 104-7, PCM layer 8 104-8, and PCM layer 9 104-9) as shown in in FIG. 1, however, in other embodiments, more or fewer PCM layers 104 are possible.

In some embodiments, the PCM layers 104 each have a similar crystallinity temperature (T_{c}). Advantageously, similar T_{c} of PCM layers 104 through the multilayer stack 110 can contribute to an expanded dynamic range (e.g., expanded R_{SET}/R_{RESET}), decreased programming current, and/or increased longevity of the PCH 100.

Each of the PCM layers 104 can have a dopant to tune the resistance (e.g., conductivity) of respective PCM layers 104 in the multilayer stack 110. Dopants can be, for example, Germanium (Ge), Nitrogen (N), Silicon (Si), Selenium (Se), Tantalum (Ta), Silicon Dioxide (SiO₂), Carbon (C), Aluminum Nitride (AlN), and/or other dopants. In some embodiments, respective PCM layers 104 have different concentrations of a same dopant, similar concentrations of different dopants, or different concentrations of different dopants. Collectively, however, the PCM layers 104 will generally exhibit varied resistance through the multilayer stack 110 as a result of the different concentrations of dopants and/or different dopants. In some embodiments, a PCM layers 104 relatively closer to the bottom electrode 108 can have a relatively higher resistance than other PCM layers 104 relatively closer to the top electrode 102. As an example, PCM layer 9 104-9 (adjacent to bottom electrode 108) can have a highest resistance of all PCM layers 104 and PCM layer 1 104-1 (adjacent to top electrode 102) can have a lowest resistance of all PCM layers 104. In some embodiments, PCM layers 104 relatively closer to the bottom electrode 108 can have a higher dopant concentration than PCM layers 104 relatively closer to the top electrode 102.

CLs 106 can be configured to physically and/or thermally isolate the PCM layers 104. Although eight CLs 106 are shown (e.g., CL 1 106-1, CL2 106-2, CL 3 106-3, CL 4 106-4, CL 5 106-5, CL 6 106-6, CL 7 106-7, and CL 8 106-8), in other embodiments, more or fewer CLs 106 are present. CLs 106 can have a higher T_{c} than PCM layers 104 such that CLs 106 do not undergo any phase-change phenomena during operation (whereas the PCM layers 104 undergo phase-change phenomena during operation). In some embodiments, CLs 106 can be semiconducting layers, now known or later developed. In some embodiments, CLs 106 comprise one or more materials selected from a group consisting of: Ti(Se, Te)₂, Tantalum Nitride (TaN), Carbon (C), Tantalum Aluminum Nitride (TaAlN), Tantalum Silicone Nitride (TaSiN), Titanium Aluminum Nitride (TiAlN), Titanium Silicone Nitride (TiSiN), Titanium Nitride (TiN), Silicone (Si), combinations of the aforementioned, derivatives of the aforementioned, and/or other materials, now known or later developed.

In some embodiments, the multilayer stack 110 has a thickness between 20-200 nanometers (nm). In some more specific embodiments, the multilayer stack 110 has a thickness between 30-100 nm. In some embodiments, the PCM layers 104 and CLs 106 each have a thickness between 1-20 nm.

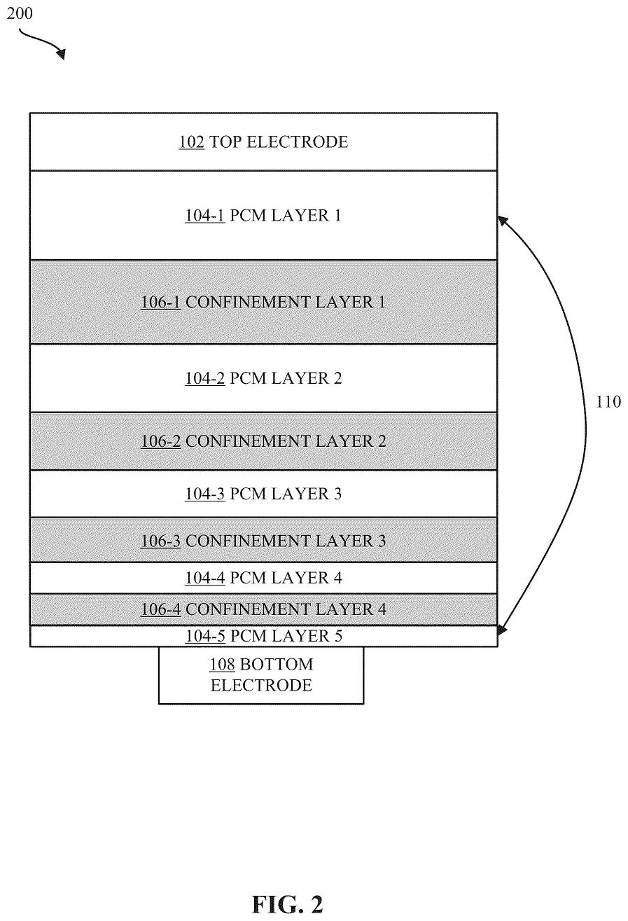

FIG. 2 illustrates a block diagram of an example PCH 200 with graded thickness in alternating PCM layers 104, in accordance with some embodiments of the present disclosure. Similar to the PCH 100 of FIG. 1, the PCH 200 of FIG. 2 illustrates multilayer stack 110 disposed between a top electrode 102 and bottom electrode 108, where the multilayer stack 110 comprises alternating PCM layers 104 and CLs 106. Although FIG. 2 includes five PCM layers 104 (e.g., PCM layer 1 104-1, PCM layer 2 104-2, PCM layer 3 104-3, PCM layer 4 104-4, and PCM layer 4 104-5), more or fewer PCM layers 104 are possible in other embodiments. Likewise, although FIG. 2 includes four CLs 106 (e.g., CL 1 106-1, CL 2 106-2, CL 3 106-3, and CL 4 106-4), more or fewer CLs 106 are possible in other embodiments.

In contrast to the PCH 100 of FIG. 1, the PCH 200 of FIG. 2 includes PCM layers 104 and/or CLs 106 with varying thicknesses. Advantageously, varying thicknesses of PCM layers 104 and/or CLs 106 can result in a varied resistance through the thickness of the PCH 200. In other words, whereas the PCH 100 of FIG. 1 relies on differing concentrations of dopants (and/or different dopants) to realize varied resistance through the PCH 100, the same variance in resistance can be achieved in the PCH 200 by varying the thicknesses of PCM layers 104 and/or CLs 106. Although FIG. 2 illustrates changes in thickness for both PCM layers 104 and CLs 106, in other embodiments, only one of PCM layers 104 or CLs 106 varies in thickness through the multilayer stack 110.

In some embodiments, relatively thinner PCM layers 104 and/or CLs 106 are located relatively closer to the bottom electrode 108 while relatively thicker PCM layers 104 and/or CLs 106 are located relatively closer to the top electrode 102. In this way, resistance in the PCH 200 is relatively higher nearer the bottom electrode 108 and relatively lower nearer the top electrode 102. For example, PCM layer 5 104-5 can be a thinnest PCM layer 104 (given its proximity to bottom electrode 108) and PCM layer 1 104-1 can be a thickest PCM layer 104 (given its proximity to the top electrode 102). Similarly, the CL 4 106-4 can be a thinnest CL 106 (given its proximity to the bottom electrode 108) and the CL 1 106-1 can be a thickest CL 106 (given its proximity to the top electrode 108).

In some embodiments, the multilayer stack 110 of PCH 200 can be between 20-200 nm in thickness. In more specific embodiments, the multilayer stack 110 of PCH 200 can be between 30-100 nm in thickness. In some embodiments, individual PCM layers 104 and CLs 106 of PCH 200 can be between 1-20 nm in thickness.

Furthermore, in some embodiments, the features of the PCH 100 of FIG. 1 and the PCH 200 of FIG. 2 can be combined in a PCH that includes both (i) variations in dopants and/or dopant concentrations in respective PCM layers 104 through the multilayer stack 110; and (ii) variations in thickness of the PCM layers 104 and/or CLs 106 through the multilayer stack 110. Such a combination can further enable tuning of the variable resistance through the multilayer stack 110.

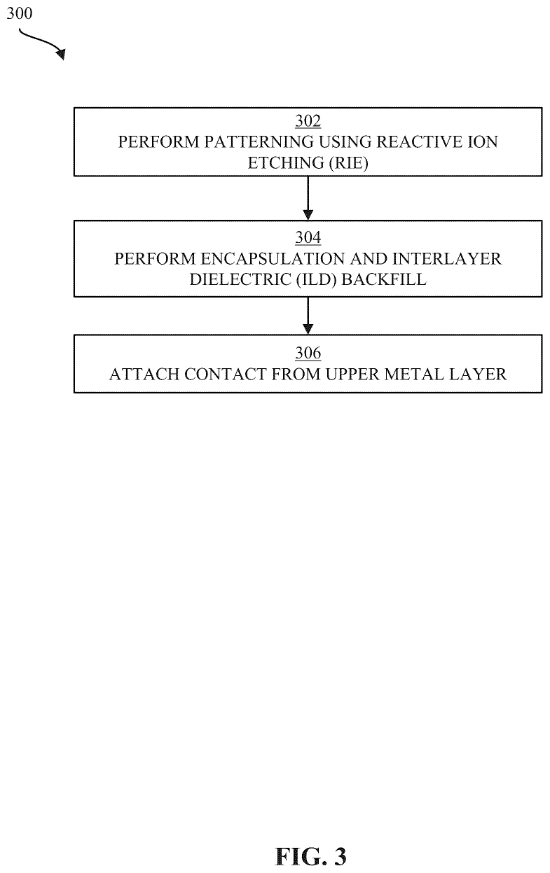

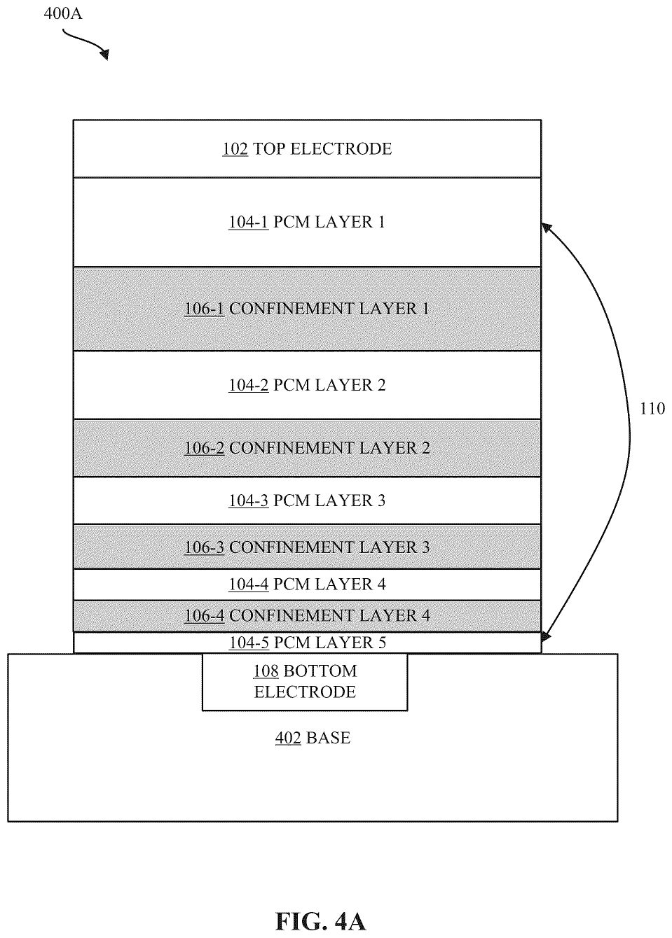

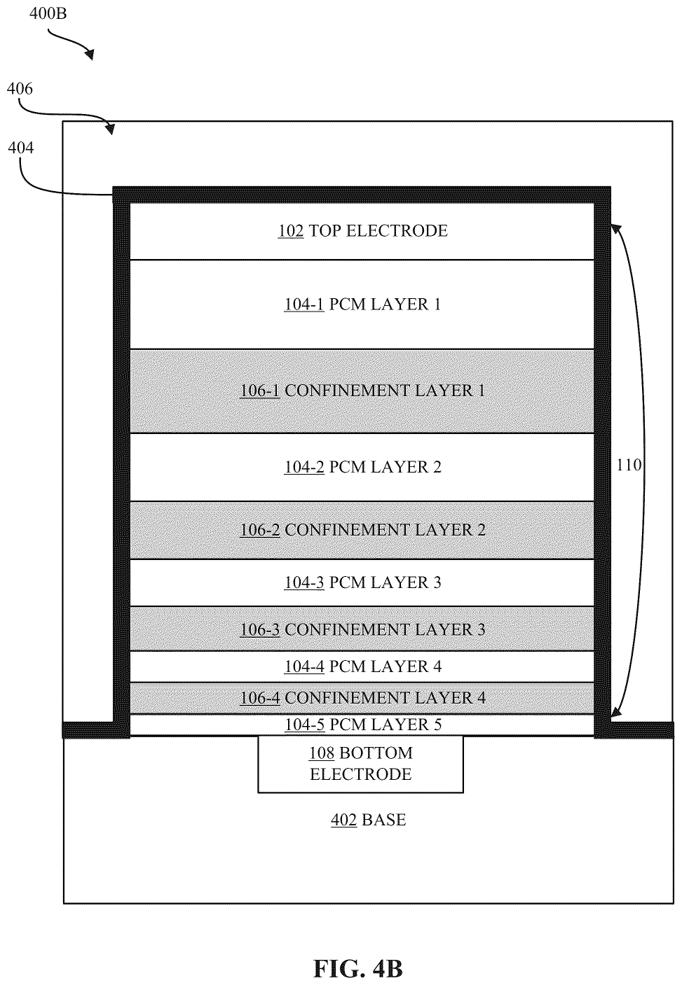

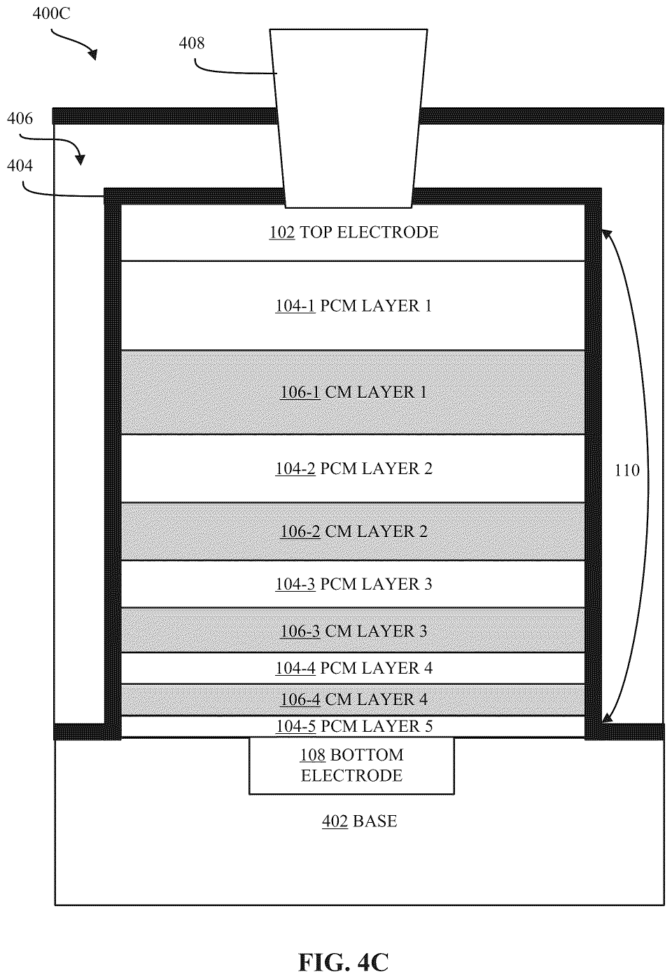

FIG. 3 illustrates a flowchart of an example method 300 for fabricating a PCH structure, in accordance with some embodiments of the present disclosure. The method 300 can be used to fabricate the PCH 100 of FIG. 1, the PCH 200 of FIG. 2, or another variation of a PCH as described herein. FIGS. 4A-4C illustrate block diagrams of different stages of the fabrication process of the PCH structure described in FIG. 3.

Referring again to FIG. 3, Operation 302 includes performing patterning using reactive ion etching (RIE). In some embodiments, co-sputtering or reactive gas tuning can be used to deposit opposing PCM layers 104 and CLs 106. FIG. 4A illustrates a block diagram of a PCH structure 400A after RIE, in accordance with some embodiments of the present disclosure. As shown in FIG. 4A, the PCH structure 400A incudes the multilayer stack 110 comprised of PCM layers 104 and CLs 106. The multilayer stack 110 is disposed between the top electrode 102 and the bottom electrode 108. The bottom electrode 108 is embedded in a base 402 (e.g., a silicone substrate), and the multilayer stack 110 is situated on top of the base 402.

Referring back to FIG. 3, operation 304 includes performing encapsulation and interlayer dielectric (ILD) backfill. FIG. 4B illustrates a block diagram of a PCH structure 400B after encapsulation and ILD backfill, in accordance with some embodiments of the present disclosure. As shown in FIG. 4B, an encapsulation layer 404 is deposited over the top electrode 102, the sides of the multilayer stack 110, and the exposed portion of the base 402. A dielectric material 406 is then backfilled on top of the encapsulation layer 404.

Referring back to FIG. 3, operation 306 includes attaching a contact from an upper metal layer to the PCH structure. FIG. 4C illustrates a block diagram of a PCH structure 400C after attaching a contact from an upper metal layer, in accordance with some embodiments of the present disclosure. As shown in FIG. 4C, the contact 408 is connected to the top electrode 102 of the PCH structure 400C.

As will be appreciated by one skilled in the art, the dimensions shown in the drawings, whether absolute or relative, are not necessarily to scale. Furthermore, the configurations shown in the drawings and described in the specification are intended to be representative of some embodiments and are simplified for ease of discussion. While some dimensions are provided in the specification, such dimensions should be understood to be examples, with other dimensions (larger or smaller) possible in other embodiments. Furthermore, any dimensions and/or concentrations described in the specification can be approximate, where the term approximate can represent a reasonable variation in dimension or concentration as a result of design factors, manufacturing capabilities, material properties, and/or other considerations. As another example, a dimension or concentration referred to as approximate or similar can be represented by an associated tolerance with the given dimension or concentration, such as ±10%, or another example tolerance. Further still, references to top, bottom, right, and left are made for ease of discussion of the drawings. Such terms should not be construed as limiting.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments can be practiced. These embodiments were described in sufficient detail to enable those skilled in the art to practice the embodiments, but other embodiments can be used and logical, mechanical, electrical, and other changes can be made without departing from the scope of the various embodiments. In the previous description, numerous specific details were set forth to provide a thorough understanding the various embodiments. But the various embodiments can be practiced without these specific details. In other instances, well-known circuits, structures, and techniques have not been shown in detail in order not to obscure embodiments.

Different instances of the word “embodiment” as used within this specification do not necessarily refer to the same embodiment, but they can. Any data and data structures illustrated or described herein are examples only, and in other embodiments, different amounts of data, types of data, fields, numbers and types of fields, field names, numbers and types of rows, records, entries, or organizations of data can be used. In addition, any data can be combined with logic, so that a separate data structure may not be necessary. The previous detailed description is, therefore, not to be taken in a limiting sense.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present disclosure has been described in terms of specific embodiments, it is anticipated that alterations and modification thereof will become apparent to the skilled in the art. Therefore, it is intended that the following claims be interpreted as covering all such alterations and modifications as fall within the true spirit and scope of the disclosure.

Any advantages discussed in the present disclosure are example advantages, and embodiments of the present disclosure can exist that realize all, some, or none of any of the discussed advantages while remaining within the spirit and scope of the present disclosure.

The following is a non-limiting list of examples of aspects of the present disclosure. Example 1 is a structure comprising: a top electrode and a bottom electrode; and a multilayer stack disposed between the top electrode and the bottom electrode, wherein the multilayer stack comprises alternating confinement layers and phase-change material layers, and wherein at least two of the phase-change material layers have different doping concentrations of at least one dopant.

Example 2 includes the features of Example 1. In this example, the at least two of the phase-change material layers have different doping concentrations of different dopants.

Example 3 includes the features of any one of Examples 1 to 2. In this example, a first phase-change material layer proximate to the bottom electrode has a higher resistance than a second phase-change material layer proximate to the top electrode.

Example 4 includes the features of any one of Examples 1 to 3. In this example, the different doping concentrations result in variable resistance through the multilayer stack.

Example 5 includes the features of any one of Examples 1 to 4. In this example, the phase-change material layers comprise a similar crystallinity temperature (T_{c}).

Example 6 includes the features of any one of Examples 1 to 5. In this example, the different doping concentrations comprise doping by at least one dopant selected from a group consisting of: Germanium (Ge), Nitrogen (N), Silicon (Si), Selenium (Se), Tantalum (Ta), Silicon Dioxide (SiO₂), Carbon (C), and Aluminum Nitride (AlN).

Example 7 includes the features of any one of Examples 1 to 6. In this example, the confinement layers comprise one or more selected from a group consisting of: Ti(Se, Te)₂, Tantalum Nitride (TaN), Carbon (C), Tantalum Aluminum Nitride (TaAlN), Tantalum Silicone Nitride (TaSiN), Titanium Aluminum Nitride (TiAlN), Titanium Silicone Nitride (TiSiN), Titanium Nitride (TiN), Silicone (Si). Optionally, the confinement layers comprise semiconducting layers.

Example 8 includes the features of any one of Examples 1 to 7. In this example, each layer in the multilayer stack has a thickness of 1-20 nanometers (nm).

Example 9 includes the features of any one of Examples 1 to 8. In this example, the multilayer stack has a thickness of 20-200 nanometers (nm).

Example 10 is a structure comprising a top electrode and a bottom electrode; and a multilayer stack disposed between the top electrode and the bottom electrode, wherein the multilayer stack comprises alternating confinement layers and phase-change material layers, and wherein at least two of the phase-change material layers have different thicknesses.

Example 11 includes the features of Example 10. In this example, a first phase-change material layer proximate to the bottom electrode has a thinner thickness than a second phase-change material layer proximate to the top electrode.

Example 12 includes the features of any one of Examples 10 to 11. In this example, the different thicknesses result in variable resistance through the multilayer stack.

Example 13 includes the features of any one of Examples 10 to 12. In this example, at least two of the confinement layers have different thicknesses.

Example 14 includes the features of any one of Examples 10 to 13. In this example, a first confinement layer proximate to the bottom electrode has a thinner thickness than a second confinement layer proximate to the top electrode.

Example 15 includes the features of any one of Examples 10 to 14. In this example, the phase-change material layers have a similar crystallinity temperature (T_{c}).

Example 16 includes the features of any one of Examples 10 to 15. In this example, the confinement layers comprise one or more selected from a group consisting of: Ti(Se, Te)₂, Tantalum Nitride (TaN), Carbon (C), Tantalum Aluminum Nitride (TaAlN), Tantalum Silicone Nitride (TaSiN), Titanium Aluminum Nitride (TiAlN), Titanium Silicone Nitride (TiSiN), Titanium Nitride (TiN), Silicone (Si). Optionally, the confinement layers comprise semiconducting layers.

Example 17 includes the features of any one of Examples 10 to 16. In this example, each layer in the multilayer stack has a thickness of 1-20 nanometers (nm).

Example 18 includes the features of any one of Examples 10 to 17. In this example, the multilayer stack has a thickness of 20-200 nanometers (nm).

Example 19 is a structure comprising a top electrode and a bottom electrode; and a multilayer stack disposed between the top electrode and the bottom electrode, wherein the multilayer stack comprises alternating confinement layers and phase-change material layers, wherein at least two of the phase-change material layers have different doping concentrations, and wherein at least two of the phase-change material layers have different thicknesses.

Example 20 includes the features of Example 19. In this example, a first phase-change material layer proximate to the bottom electrode has a higher resistance than a second phase-change material layer proximate to the top electrode.

What is claimed is:

1. A structure comprising:
a top electrode and a bottom electrode; and
a multilayer stack disposed between the top electrode and the bottom electrode, wherein the multilayer stack comprises alternating confinement layers and phase-change material layers, and wherein at least two of the phase-change material layers have different doping concentrations of at least one dopant.

2. The structure of claim 1, wherein the at least two of the phase-change material layers have different doping concentrations of different dopants.

3. The structure of claim 1, wherein a first phase-change material layer proximate to the bottom electrode has a higher resistance than a second phase-change material layer proximate to the top electrode.

4. The structure of claim 1, wherein the different doping concentrations result in variable resistance through the multilayer stack.

5. The structure of claim 1, wherein the phase-change material layers comprise a similar crystallinity temperature (T_{c}).

6. The structure of claim 1, wherein the different doping concentrations comprise doping by at least one dopant selected from a group consisting of: Germanium (Ge), Nitrogen (N), Silicon (Si), Selenium (Se), Tantalum (Ta), Silicon Dioxide (SiO₂), Carbon (C), and Aluminum Nitride (AlN).

7. The structure of claim 1, wherein the confinement layers comprise one or more selected from a group consisting of: Ti(Se, Te)₂, Tantalum Nitride (TaN), Carbon (C), Tantalum Aluminum Nitride (TaAlN), Tantalum Silicone Nitride (TaSiN), Titanium Aluminum Nitride (TiAlN), Titanium Silicone Nitride (TiSiN), Titanium Nitride (TiN), Silicone (Si).

8. The structure of claim 1, wherein each layer in the multilayer stack has a thickness of 1-20 nanometers (nm).

9. The structure of claim 1, wherein the multilayer stack has a thickness of 20-200 nanometers (nm).

10. A structure comprising:
a top electrode and a bottom electrode; and
a multilayer stack disposed between the top electrode and the bottom electrode, wherein the multilayer stack comprises alternating confinement layers and phase-change material layers, and wherein at least two of the phase-change material layers have different thicknesses.

11. The structure of claim 10, wherein a first phase-change material layer proximate to the bottom electrode has a thinner thickness than a second phase-change material layer proximate to the top electrode.

12. The structure of claim 10, wherein the different thicknesses result in variable resistance through the multilayer stack.

13. The structure of claim 10, wherein at least two of the confinement layers have different thicknesses.

14. The structure of claim 13, wherein a first confinement layer proximate to the bottom electrode has a thinner thickness than a second confinement layer proximate to the top electrode.

15. The structure of claim 10, wherein the phase-change material layers have a similar crystallinity temperature (T_{c}).

16. The structure of claim 10, wherein the confinement layers comprise one or more selected from a group consisting of: Ti(Se, Te)₂, Tantalum Nitride (TaN), Carbon (C), Tantalum Aluminum Nitride (TaAlN), Tantalum Silicone Nitride (TaSiN), Titanium Aluminum Nitride (TiAlN), Titanium Silicone Nitride (TiSiN), Titanium Nitride (TiN), Silicone (Si).

17. The structure of claim 10, wherein each layer in the multilayer stack has a thickness of 1-20 nanometers (nm).

18. The structure of claim 10, wherein the multilayer stack has a thickness of 20-200 nanometers (nm).

19. A structure comprising:
a top electrode and a bottom electrode; and
a multilayer stack disposed between the top electrode and the bottom electrode, wherein the multilayer stack comprises alternating confinement layers and phase-change material layers, wherein at least two of the phase-change material layers have different doping concentrations, and wherein at least two of the phase-change material layers have different thicknesses.

20. The structure of claim 19, wherein a first phase-change material layer proximate to the bottom electrode has a higher resistance than a second phase-change material layer proximate to the top electrode.
